(19) United States
(12) Patent Application Publication
(10) Pub. No.: US 2022/0074836 A1
(43) Pub. Date: Mar. 10, 2022

(54) METHOD FOR DETERMINING INITIATION POSITION OF FRETTING FATIGUE CRACKS

(71) Applicant: Beijing Institute of Technology, Beijing (CN)

(72) Inventors: Li JIAO, Beijing (CN); Huiqing GU, Beijing (CN); Xibin WANG, Beijing (CN); Pei YAN, Beijing (CN); Shiqi CHEN, Beijing (CN); Binxing MA, Beijing (CN); Jiabin LIANG, Beijing (CN)

(73) Assignee: Beijing Institute of Technology, Beijing (CN)

(21) Appl. No.: 17/397,528

(22) Filed: Aug. 9, 2021

(30) Foreign Application Priority Data
Sep. 10, 2020 (CN) 202010946102.8
Feb. 19, 2021 (CN) 202110191634. X

(51) Int. Cl. G01N 3/06; G01B 11/24

(52) U.S. Cl. CPC G01N 3/068; G01B 11/2441; G01N 2203/0647; G01N 2203/0064; G01N 2203/0073

(57) ABSTRACT

The present disclosure relates to a method for determining initiation positions of fretting fatigue cracks. The processed inner circular hole test workpiece is placed on a stage of an optical microscope, wherein the inner hole surface to be measured is perpendicular to the scanning beam direction of the microscope; measurement is performed along the real contact orientation between the inner hole surface of the inner circular hole test workpiece and the pin shaft. From the measured surface morphology and profile image, rectangular target areas with a coverage rate of 75%˜90%, and the amplitude distribution function, surface skewness and surface kurtosis values of the respective surface profiles are extracted from the target areas. By comparing the positive/negative of and the magnitude of the skewness and kurtosis values measured in the target areas, the side where the initiation position of fretting fatigue cracks is located can be determined.

### CROSS REFERENCE TO RELATED APPLICATION(S)

This patent application claims the benefit and priority of Chinese Patent Application No. 202010946102.8, filed on Sep. 10, 2020, and 202110191634.X. filed on Feb. 19, 2021, the disclosure of which is incorporated by reference herein in its entirety as part of the present applications.

### TECHNICAL FIELD

The present disclosure relates to the research on method for predicting initiation of fretting fatigue cracks, in particular to a method for determining initiation positions of fretting fatigue cracks.

### BACKGROUND ART

Inner circular hole features are widely found in various mechanical parts, equipment, and products, such as mating holes for connecting crankshafts and rods of automobile engines, piston cylinders, mounting pin holes of crane hooks, and various connecting holes. The machining surface quality and surface integrity parameters of such kind of holes play a critical role in the safe operation, reliability, and stability of the whole machine. In this kind of mechanically connected structural parts, it is prone to inducing complex and tiny relative movements in the order of tens of microns between the connected components under random cyclic loads such as vibration, and the resultant fretting damage will lead to premature nucleation of fatigue cracks, making the fatigue life of the component far less than the plain fatigue without fretting. This is an important reason for the fatigue fracture failure of connecting parts, and seriously reduces the service life and service safety of the component. The prediction of the initiation position of fretting fatigue cracks, and then providing guidance to apply reliable surface enhancement and protection measures, is an important topic on function and performance-oriented manufacturing (high performance manufacturing).

The patent Ser. No. 10/873,2035A discloses a method/standard for determining fretting fatigue life of tongued joint structures on the basis of a determination of strain or displacement singularity caused by crack initiation. This method requires a design of special fixture and uses high-precision strain or displacement measurement equipment, which is complicated in operation and costly. Patent SN110348056 A discloses a fretting fatigue life prediction model based on continuum damage mechanics and a method thereof. This model requires establishment of a complex model based on nonlinear fatigue damage accumulation and introduces the critical plane energy density parameter, while it has disadvantages such as difficulty in model establishing, accompanying by a complex and time-consuming calculation process, etc. In addition, the models and prediction methods established in the above patents are all based on Hertz contact model, while in real engineering applications: (1) most contacts do not meet Hertz contact conditions; (2) fretting fatigue cracks all initiate due to wear damage of micro-protrusions on the contact surface, but the above mentioned models do not consider the influence of the surface texture bearing the micro-protrusions, which leads to a big gap between the predicted results by the method disclosed in the above patent documents and the fact.

In conclusion, the technologies in the prior art disclosed in the above documents have following shortcomings: (1) since the fretting fatigue cracks all start from the contact surface, models in the prior art do not consider the influence of texture parameters of the contact surface on crack initiation; (2) there is a lack of a simple method to determine the initiation position of fretting fatigue cracks based on surface texture parameters; (3) no effective method for predicting the crack initiation position is established yet for components that do not meet Hertz contact conditions. Therefore, the method in the prior art for predicting initiation of fretting fatigue cracks is still insufficient, which requires further improvement and perfection.

### SUMMARY

The technical problem to be solved by the disclosure is to provide a method for judging the initiation position of fretting fatigue cracks through surface texture parameters, for which the measurement of texture parameter values of skewness and kurtosis of a machined surface is performed in a specific measuring direction, and the initiation position of fretting fatigue cracks on a component is determined by the positive or negative property of the surface skewness, as well as by comparing the magnitude of skewness and kurtosis values that measured at different areas on the machined surface.

To solve the problems mentioned above, technical schemes adopted in the present disclosure are as follows:

(1) Feature Division on Inner Circular Hole Test Workpiece

The inner circular hole test workpiece is a plate-shaped structural specimen with a uniform thickness, a peripheral profile surface shaped like a symmetrical octagon, and a cylindrical through hole along the thickness direction is arranged at the symmetrical center of the workpiece. A coordinate system O—X_{c}Y_{c}Z_{c} is established for the inner circular hole test workpiece, and, by passing across a cylindrical through the hole axis, a quarter volume of the inner circular hole test workpiece sample is cut off from the workpiece, along two planes of symmetry perpendicular to each other, X_{c}—O—Z_{c} and Y_{c}—O—Z_{c}, as a test workpiece sample. The coordinate system O—X_{c}Y_{c}Z_{c} of the inner circular hole test workpiece sample is rotated clockwise by 45 degrees around the OZ_{c} axis to construct a sample coordinate system O—XₛYₛZₛ, and to indicate an inner hole surface, an inner hole axis, a symmetry plane, and a measurement placement plane on the sample, wherein the planes of symmetry pass through the inner hole axis and are parallel to an Yₛ—O—Zₛ plane of the coordinate system O—XₛYₛZₛ of the sample.

(2) Measurement of Surface Morphology and Profile of Inner Hole Surface

An optical microscope related coordinate system O_{w}—X_{w}Y_{w}Z_{w} is established, and the surface morphology and profile of the sample is measured. With the placement plane, the sample is placed on a stage of an optical microscope such as a white light interferometer or a laser confocal microscope. By adjusting the sample based on the sample coordinate system O—XₛYₛZₛ, the inner hole axis of the inner hole surface to be measured is parallel to the X_{w} axis of the microscope coordinate system, and the microscope scanning beam irradiates the bottom position at center of the inner hole surface to be measured, so as to ensure that the inner hole surface to be measured is perpendicular to the direction in which the microscope scanning beam is located. Measurement is performed along the real contact orientation between the inner hole surface of the inner circular hole test workpiece and the pin shaft, so that a scanning path of the microscope is perpendicular to the inner hole axis, in order to measure the surface morphology and profile image of the inner hole surface of the test workpiece.

(3) Target Area Selection

On the measured image of the surface morphology and profile, a rectangular first target area and a rectangular second target area with a coverage of 75%˜90% are symmetrically selected on each side against the planes of symmetry passing through the inner hole axis, which covers the morphology information of the whole inner hole surface to be measured to a greater extent, and also eliminates possible processing defects in the peripheral boundary area of the sample and the interference caused by unmeasurable curved surface areas. The amplitude distribution functions APD_{L} and APD_{R}, the surface skewness R_{skL} and R_{skR}, the surface kurtosis values R_{kuL} and R_{kuR} of respective surface profiles are extracted from the target area.

(4) Defining the Comparison Set of Surface Skewness and Surface Kurtosis Values, as Shown in Formula (I):

Nᵤ={max(R_{skL},R_{skR})}∪{max(R_{kuL},R_{kuR})} (I)

In formula (I), Nᵤ is a marking that notes a comparison set of large skewness values and large kurtosis values on both left sides and right sides; s_{skL} and R_{skR} are respectively skewness values of surface texture parameters of the first target area and the second target area, and R_{kuL} and R_{kuR} are respectively kurtosis values of surface texture parameters of the first target area and the second target area, wherein max refers to the larger one among the two.

(5) Determining the Initiation Position of Fretting Fatigue Cracks

By comparing the magnitude of the skewness and kurtosis values measured in the first target area and the second target area according to formula (I), it is determined according to formula (II) below for the fretting fatigue crack initiation position corresponding to the surface texture parameters, for which the crack initiates at the side with larger skewness and kurtosis values. Since greater skewness and kurtosis values indicate that the micro-morphology of the inner hole surface to be measured shows more circular microscopic wave bottoms and sharp wave peaks, while smaller skewness and kurtosis values indicate that the micro-morphology of the inner hole surface to be measured shows more sharp microscopic wave bottoms and circular wave peaks. The higher the skewness and kurtosis values are, the more microscopic contact protrusions there will be, the larger the contact area is, the greater the contact force will be, the smaller the skewness and kurtosis values are, the less obvious the correlation features will be. The larger the skewness and kurtosis values are, the more and higher the microscopic sharp peaks will be, which leads to significant fretting wear in the contact area between the inner circular hole test workpiece sample and the pin shaft during fretting, results in aggravating fretting damage, deterioration of the contact surface state, and as a result the micro-cracks initiated.

$$L = \{ \begin{matrix}Left , {N}_{u} = \{ {R}_{skL} , {R}_{kuL} \} \\ Right , {N}_{u} = \{ {R}_{skR} , {R}_{kuR} \} \\ Left , {N}_{u} = \{ {R}_{skL} , {R}_{kuR} \} and {R}_{kuR} + 3 < \frac{{R}_{skL}}{σ} {\sum }_{i = 1}^{n} ( {x}_{i} - \overline{x} ) \\ Right , {N}_{u} = \{ {R}_{skL} , {R}_{kuR} \} and {R}_{kuR} + 3 > \frac{{R}_{skL}}{σ} {\sum }_{i = 1}^{n} ( {x}_{i} - \overline{x} ) \\ Left , {N}_{u} = \{ {R}_{skR} , {R}_{kuL} \} and {R}_{kuL} + 3 > \frac{{R}_{skR}}{σ} {\sum }_{i = 1}^{n} ( {x}_{i} - \overline{x} ) \\ Right , {N}_{u} = \{ {R}_{skR} , {R}_{kuL} \} and {R}_{kuL} + 3 < \frac{{R}_{skR}}{σ} {\sum }_{i = 1}^{n} ( {x}_{i} - \overline{x} )\end{matrix} \qquad ( II )$$

In formula (II), L is a marking that notes the initiation position of fretting fatigue cracks, xᵢ is a i data point measured in the target area, n is a number of total data points measured in the target area, x̅ is an average value of data measured in the target area side, and σ is a standard deviation of data values measured in the target area.

Furthermore, before the measurement, all test workpieces should be put into ultrasonic cleaning equipment for cleaning to remove residual oil, particles, and dust on its surface.

In comparison to the prior art, the present disclosure provides the following advantages: at present, there is no direct and concise method for determining the initiation position of fretting fatigue cracks in the prior art. The present disclosure applies for comprehensively analyzing the surface texture parameters of the feature area of a test workpiece and the initiation position of fretting fatigue cracks, and directly establishes the dependency relationship between the initiation position of fretting fatigue cracks and the surface texture parameters through texture parameters, such as surface skewness and kurtosis, thereby giving targeted instructions on the surface enhancement and protection technological design, so as to obtain surface texture features with the best anti-fretting fatigue performance. The amplitude distribution function, surface skewness and surface kurtosis values of machined surfaces are measured by optical microscopes, and the initiation position of fretting fatigue cracks can be determined by comparing the positive/negative of and magnitude of the skewness and kurtosis measured in different positions and regions, thus avoiding the difficulty of predicting the initiation position of cracks due to complex modeling. The surface profile measurement is carried out along the real contact orientation between the inner hole surface of the test workpiece and the pin shaft in the manner that the scanning path of the microscope lens is perpendicular to the axial direction of the inner hole, which can reflect that the measured surface profile, skewness, and kurtosis values are consistent with those of the surface state of the component in real contact. By symmetrically selecting the target areas with the coverage of 75%-90% on each side, and extracting the amplitude distribution function, surface skewness and surface kurtosis of the respective surface profiles from the target areas, the morphology information of the whole surface is covered to a large extent, and possible processing defects in the peripheral boundary area and the interference caused by unmeasurable curved surface areas are eliminated.

### BRIEF DESCRIPTION OF THE DRAWINGS

In order to illustrate the embodiments of the present disclosure or in the prior art more clearly, the accompanying drawings required in the embodiments or prior art will be briefly introduced below. Apparently, the drawings in the following description are only some embodiments of the present disclosure, and those of ordinary skills in the art may obtain other drawings according to these drawings without creative work.

FIG. 1 is a schematic diagram of the contact between a pin shaft and an inner circular hole test workpiece;

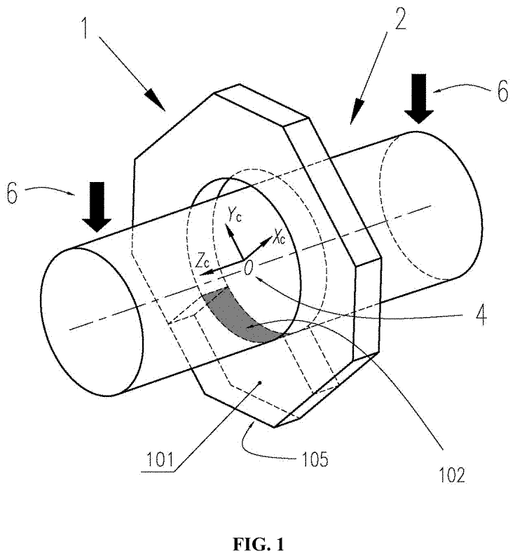

FIG. 2 is a schematic diagram of the surface morphology and profile measurement method according to the present disclosure;

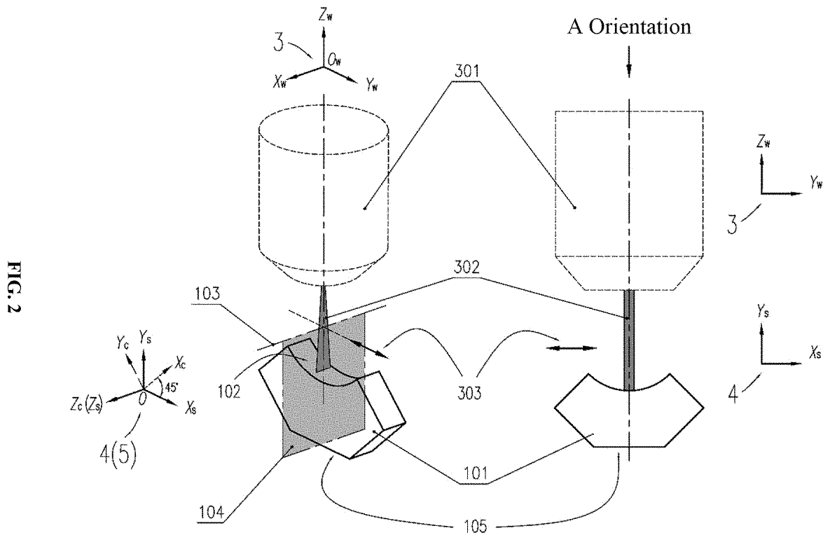

FIG. 3 is a schematic diagram of target area selection for extracting a surface profile amplitude distribution function, surface skewness and surface kurtosis values according to the present disclosure;

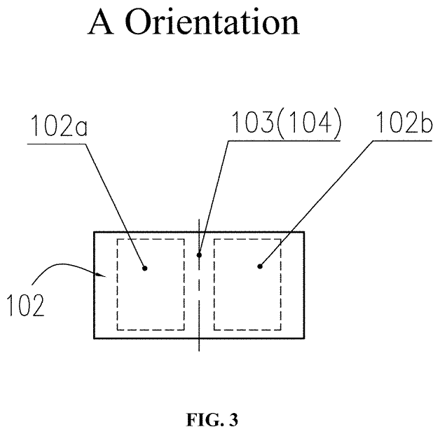

FIG. 4 is a flow chart of the method in the present disclosure;

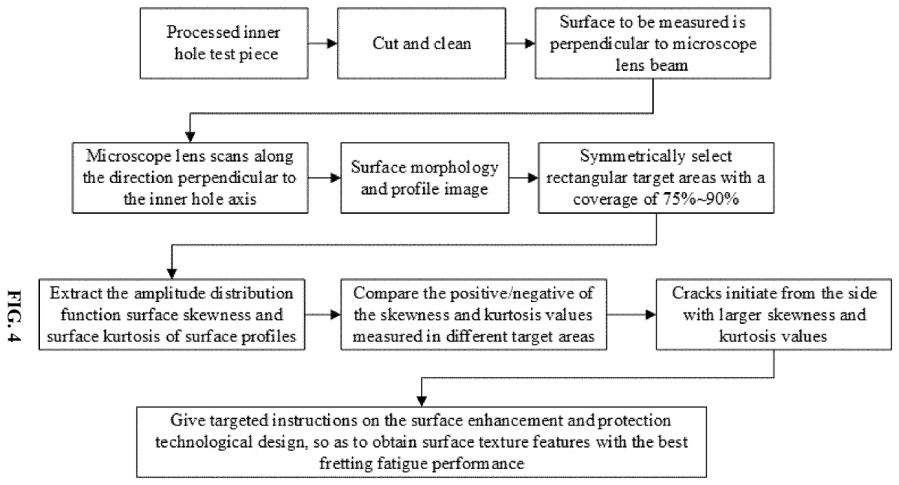

FIG. 5 is a schematic diagram of target area selection for extracting a surface profile amplitude distribution function, surface skewness and surface kurtosis values according to an embodiment in the present disclosure;

FIG. 6 is a comparison diagram of numerical results of surface profile amplitude distribution function, surface skewness and surface kurtosis according to an embodiment of the present disclosure;

FIG. 7 shows the fretting fatigue crack propagation path obtained by testing in an embodiment of the present disclosure;

The reference numerals in the figures include: 1 inner circular hole test workpiece, 101 sample, 102 inner hole surface, 102a first target area, 102b second target area, 103 inner hole axis, 104 plane of symmetry, 105 measurement and placement plane, 2 pin shaft, 3 microscope coordinate system, 301 microscope scanning lens, 302 microscope scanning beam, 303 microscope scanning path, 4 test workpiece coordinate system, 5 sample coordinate system, and 6 fatigue load.

### DETAILED DESCRIPTION OF THE EMBODIMENTS

Technical schemes in the embodiments of the present disclosure will be described clearly and completely with reference to the accompanying drawings thereof. Apparently, the embodiments described herein are only part of, not all of, embodiments in the present disclosure. Based on the embodiments of the present disclosure, all other embodiments obtained by those of ordinary skills in the art without creative work belong to the scope claimed by the present disclosure.

(1) Feature Division on Inner Circular Hole Test Workpiece 1

The inner circular hole test workpiece 1 is a plate-shaped structural specimen with a uniform thickness, a peripheral profile surface shaped like a symmetrical octagon, and a cylindrical through hole along the thickness direction is arranged at the symmetrical center of the workpiece. A coordinate system 4 is established for the inner circular hole test workpiece 1, and, by passing across a cylindrical through the hole axis, a quarter volume of the inner circular hole test workpiece sample is cut off from the workpiece, along two planes of symmetry perpendicular to each other, X_{c}—O—Zₑ and Y_{c}—O—Z_{c}, as a sample 101. The coordinate system 4 is rotated clockwise by 45 degrees around the OZ_{c} axis to construct a sample coordinate system 5, so as to determine an inner hole surface 102, an inner hole axis 103, planes of symmetry 104 and a measurement and placement plane 105 mating with a pin shaft 2 on the sample 101, wherein the planes of symmetry 104 pass through the inner hole axis 103 and are parallel to an Yₛ—O—Zₛ plane of the sample coordinate system 5.

(2) Measurement of Surface Morphology and Profile of Inner Hole Surface

An optical microscope related coordinate system 3 is established, and the surface morphology and profile of the sample 101 is measured. With and the placement plane 105, the sample 101 is placed on a stage of an optical microscope such as a white light interferometer or a laser confocal microscope. By adjusting the sample 101 based on the sample coordinate system 5, the inner hole axis 103 of the inner hole surface 102 to be measured is parallel to the X_{w} axis of the microscope coordinate system 3, and the microscope scanning beam 302 irradiates the bottom position at center of the inner hole surface 102 to be measured, so as to ensure that the inner hole surface 102 to be measured is perpendicular to the direction in which the microscope scanning beam 302 is located. Measurement is performed along the real contact orientation between the inner hole surface of the inner circular hole test workpiece 1 and the pin shaft 2, so that a scanning path 303 of the microscope is perpendicular to the inner hole axis 103, in order to measure the surface morphology and profile image of the inner hole surface 102 of the sample 101.

(3) Target Area Selection

On the measured image of the surface morphology and profile, a rectangular first target area 102a and a rectangular second target area 102b with a coverage of 75%˜90% are symmetrically selected on each side relative to the planes of symmetry 104 passing through the inner hole axis 103, which covers the morphology information of the whole inner hole surface to be measured to a greater extent, and also eliminates possible processing defects in the peripheral boundary area of the sample and the interference caused by unmeasurable curved surface areas. The amplitude distribution functions APD_{L} and APD_{R}, the surface skewness R_{skL} and R_{skR}, the surface kurtosis values R_{kuL} and R_{kuR} of respective surface profiles are extracted from the target area 102a and 102b.

(4) Defining the Comparison Set of Surface Skewness and Surface Kurtosis Values, as Shown in Formula (I):

Nᵤ={max(R_{skL},R_{skR})}∪{max(R_{kuL},R_{kuR})} (I)

In formula (I), Nᵤ is a marking that notes a comparison set of large skewness values and large kurtosis values on both left sides and right sides; R_{skL} and R_{skR} are respectively skewness values (accounting to two decimal places) of surface texture parameters of the first target area 102a and the second target area 102b, and R_{kuL} a R_{kuR} are respectively kurtosis values (accounting to two decimal places) of surface texture parameters of the first target area 102a and the second target area 102b, wherein max refers to the larger one among the two.

(5) Determining the initiation position of fretting fatigue cracks

By comparing the magnitude of the skewness and kurtosis values measured in the first target area and the second target area according to formula (I), it is determined according to formula (II) below for the fretting fatigue crack initiation position corresponding to the surface texture parameters, for which the cracks initiate at the side with larger skewness and kurtosis values.

$$L = \{ \begin{matrix}Left , {N}_{u} = \{ {R}_{skL} , {R}_{kuL} \} \\ Right , {N}_{u} = \{ {R}_{skR} , {R}_{kuR} \} \\ Left , {N}_{u} = \{ {R}_{skL} , {R}_{kuR} \} and {R}_{kuR} + 3 < \frac{{R}_{skL}}{σ} {\sum }_{i = 1}^{n} ( {x}_{i} - \overline{x} ) \\ Right , {N}_{u} = \{ {R}_{skL} , {R}_{kuR} \} and {R}_{kuR} + 3 > \frac{{R}_{skL}}{σ} {\sum }_{i = 1}^{n} ( {x}_{i} - \overline{x} ) \\ Left or right , {N}_{u} = \{ {R}_{skL} , {R}_{kuR} \} and {R}_{kuR} + 3 = \frac{{R}_{skL}}{σ} {\sum }_{i = 1}^{n} ( {x}_{i} - \overline{x} ) \\ Left , {N}_{u} = \{ {R}_{skR} , {R}_{kuL} \} and {R}_{kuL} + 3 > \frac{{R}_{skR}}{σ} {\sum }_{i = 1}^{n} ( {x}_{i} - \overline{x} ) \\ Right , {N}_{u} = \{ {R}_{skR} , {R}_{kuL} \} and {R}_{kuL} + 3 < \frac{{R}_{skR}}{σ} {\sum }_{i = 1}^{n} ( {x}_{i} - \overline{x} ) \\ Left or right , {N}_{u} = \{ {R}_{skR} , {R}_{kuL} \} and {R}_{kuL} + 3 = \frac{{R}_{skR}}{σ} {\sum }_{i = 1}^{n} ( {x}_{i} - \overline{x} )\end{matrix} \qquad ( II )$$

In formula (II), L is a marking that notes the initiation position of fretting fatigue cracks, xᵢ is a i data point measured in the target area, n is a number of total data points measured in the target area, x̅ is an average value of data measured in the target area side, and σ is a standard deviation of data values measured in the target area. In addition, in formula (2), when

$${N}_{u} = \{ {R}_{skL} , {R}_{kuR} \} \begin{matrix}• \\ • \\ • \\ \\ \end{matrix} {R}_{kuR} + 3 = \frac{{R}_{skL}}{σ} {\sum }_{i = 1}^{n} ( {x}_{i} - \overline{x} ) or {N}_{u} = \{ {R}_{skR} {,}_{kuL} \} \begin{matrix}• \\ • \\ • \\ \\ \end{matrix} {R}_{kuL} + 3 = \frac{{R}_{skR}}{σ} {\sum }_{i = 1}^{n} ( {x}_{i} - \overline{x} ) ,$$

it is possibly not able to completely determine whether fretting fatigue cracks originate on the left side or the right side. However, there is very little probability that Nᵤ satisfy such cases. During actual workpiece machining, surface texture parameter relations satisfying these two cases rarely exist for machined surfaces. In order to make the relation a closed loop, the conditions of the two minimum probability events mentioned above are also listed in formula (2) as well.

Before the measurement, all samples 101 cut off from the test workpiece 1 should be put into ultrasonic cleaning equipment for cleaning to remove residual oil, particles, and dust on its surface.

By texture parameters such as surface skewness and kurtosis, a dependence relationship is directly established between the initiation position of fretting fatigue cracks on the surface and surface texture parameters, which gives targeted instruction on the process design of surface enhancement and protection treatment in order to obtain the surface texture features with the best fretting fatigue resistance.

Specific Embodiments Include:

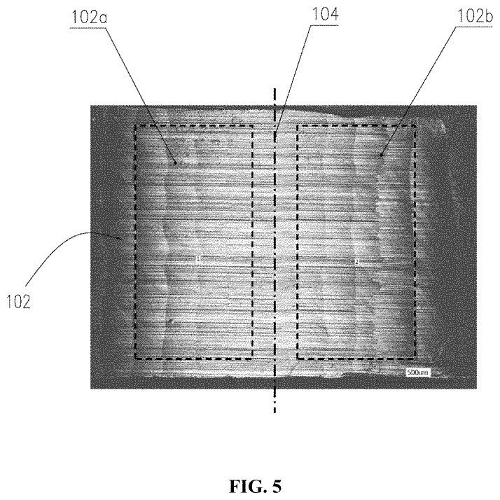

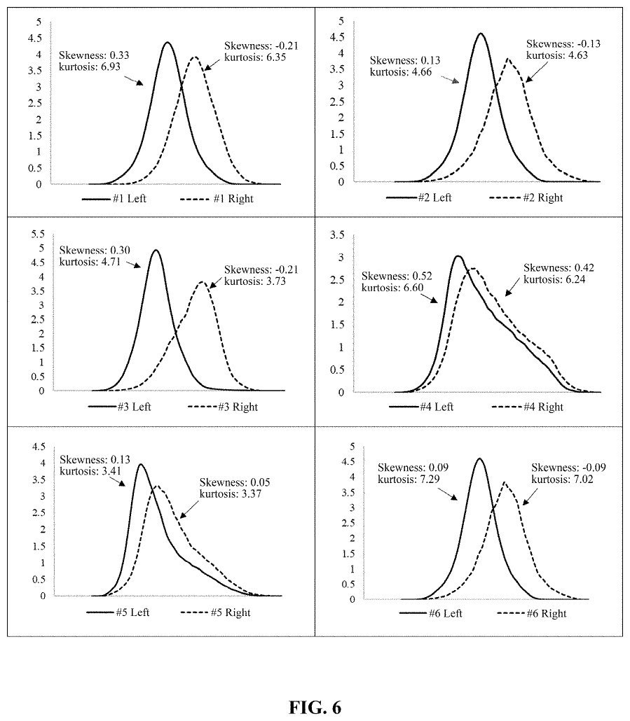

Taking the test workpiece 1 with a circular hole diameter of φ12.2 mm as an example, six different groups of machined inner hole surfaces 102 are obtained through six different milling parameters, and the test workpieces are numbered as #1˜#6. Using the method proposed by the present disclosure. The surface morphology of the inner hole surface 102 is measured along the plane of symmetry 104, as shown in FIG. 5. On this basis, the target areas 102a and 102b are demarcated according to the area coverage rate of 80%, and their surface skewness and kurtosis values are extracted and listed in Table 1, with the results being shown in FIG. 6.

TABLE 1
Skewness and Kurtosis values of circular hole
surfaces of different test workpieces

| Test | Skewness value: | | Kurtosis value: | |
|---|---|---|---|---|
| workpieces | Left side | Right side | Left side | Right side |
| #1 | 0.33 | −0.21 | 6.93 | 6.35 |
| #2 | 0.13 | −0.13 | 4.66 | 4.63 |
| #3 | 0.30 | −0.21 | 4.71 | 3.73 |
| #4 | 0.52 | 0.42 | 6.60 | 6.24 |
| #5 | 0.13 | 0.05 | 3.41 | 3.37 |
| #6 | 0.09 | −0.09 | 7.29 | 7.02 |

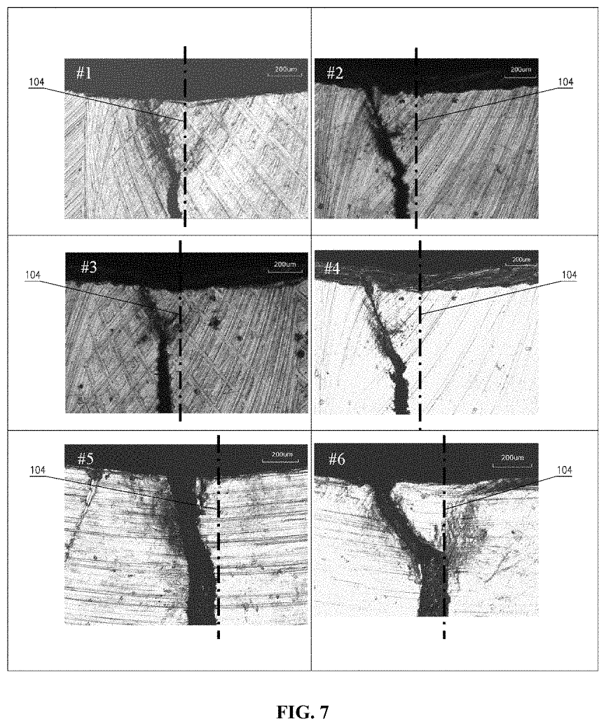

By substituting the numerical values into formula (I) and formula (II), it is found that the skewness value and kurtosis value on the left side are both larger than those on the right side in the measurement target areas 102a and 102b of the inner hole surface 102, so it can be determined that fretting fatigue cracks all initiate on the left side. By combining this result with the crack propagation path (see FIG. 7) obtained by fretting fatigue testing under a fatigue load 6, it is found that the tested results are consistent with the predicted results, namely, fretting fatigue cracks always initiate on the side with larger skewness value and kurtosis value, and eventually propagate and result in fatigue failure of the test workpieces.

The embodiments described above are only preferred embodiments of the present disclosure, but not an exhaustive list of feasible implementations of the present disclosure. For those of ordinary skill in the art, any obvious changes made without departing from the principle and spirit of the present disclosure should be considered to be included in the claimed scope of the claims of the present disclosure.

What is claimed is:

1. A method for determining initiation position of fretting fatigue cracks, comprising:
In Step 1, classifying features of a processed inner circular hole test workpiece (1), constructing a coordinate system O—X_{c}Y_{c}Z_{c} (4) of the inner circular hole test workpiece (1), cutting off a sample (101) from the inner circular hole test workpiece (1), and rotating the coordinate system O—X_{c}Y_{c}Z_{c} of the inner circular hole test workpiece (1) clockwise by 45 degrees around an OZ_{c} axis to construct a coordinate system O—XₛYₛZₛ (5) of the sample (101), so as to determine an inner hole surface (102), an inner hole axis (103), planes of symmetry (104) and a measurement and placement plane (105) mating with a pin shaft (2) on the sample (101), wherein the planes of symmetry (104) pass through the inner hole axis (103) and are parallel to an Yₛ—O—Zₛ plane of the coordinate system O—XₛYₛZₛ (5) of the sample (101);
In Step 2, establishing an optical microscope coordinate system O_{w}—X_{w}Y_{w}Z_{w} (3), and measuring a surface morphology and profile of the sample (101);
In Step 3, according to the distribution of surface morphology and profile in Step 2, a first target area (102a) and a second target area (102b) are respectively selected on both sides of the planes of symmetry (104), and amplitude distribution functions APD_{L} and APD_{R}, the surface skewness R_{skL} and R_{skR}, the surface kurtosis values R_{kuL} and R_{kuR} of respective surface profiles are extracted from the first target area (102a) and the second target area (102b);
(4) Defining a comparison set of surface skewness and surface kurtosis values as shown in formula (I):
Nᵤ={max(R_{skL},R_{skR})}∪{max(R_{kuL},R_{kuR})} (I)
In formula (I), Nᵤ is a marking for noting a comparison set of large skewness values and large kurtosis values on both sides of the first target area (102a) and the second target area (102b); R_{skL} and R_{skR} are respectively skewness values (accounting to two decimal places) of surface texture parameters of the first target area (102a) and the second target area (102b), and R_{kuL} and R_{kuR} are respectively kurtosis values (accounting to two decimal places) of surface texture parameters of the first target area (102a) and the second target area (102b), wherein max refers to the larger one among the two;
(5) Determining the side where the fretting fatigue crack initiation position is located, wherein it is determined according to formula (II) below for the fretting fatigue crack initiation position corresponding to the surface texture parameters, for which the crack initiates at the side with larger skewness and kurtosis:
$$L = \{ \begin{matrix}Left , {N}_{u} = \{ {R}_{skL} , {R}_{kuL} \} \\ Right , {N}_{u} = \{ {R}_{skR} , {R}_{kuR} \} \\ Left , {N}_{u} = \{ {R}_{skL} , {R}_{kuR} \} and {R}_{kuR} + 3 < \frac{{R}_{skL}}{σ} {\sum }_{i = 1}^{n} ( {x}_{i} - \overline{x} ) \\ Right , {N}_{u} = \{ {R}_{skL} , {R}_{kuR} \} and {R}_{kuR} + 3 > \frac{{R}_{skL}}{σ} {\sum }_{i = 1}^{n} ( {x}_{i} - \overline{x} ) \\ Left , {N}_{u} = \{ {R}_{skR} , {R}_{kuL} \} and {R}_{kuL} + 3 > \frac{{R}_{skR}}{σ} {\sum }_{i = 1}^{n} ( {x}_{i} - \overline{x} ) \\ Right , {N}_{u} = \{ {R}_{skR} , {R}_{kuL} \} and {R}_{kuL} + 3 < \frac{{R}_{skR}}{σ} {\sum }_{i = 1}^{n} ( {x}_{i} - \overline{x} )\end{matrix} \qquad ( II )$$
In formula (II), L is a marking that notes the initiation position of fretting fatigue cracks, xᵢ is a i data point measured in the target area, n is a number of total data points measured in the target area, x̅ is an average value of data measured in the target area side, and σ is a standard deviation of data values measured in the target area, wherein the first target area (102a) corresponds to a crack initiation position on the left side, and the second target area (102b) corresponds to a crack initiation position on the right side.

2. The method for determining initiation position of fretting fatigue cracks according to claim 1, wherein the Step 1 comprises: the inner circular hole test workpiece (1) is a plate-shaped structural specimen with a uniform thickness, a peripheral profile surface shaped like a symmetrical octagon, and a cylindrical through hole along the thickness direction is arranged at the symmetrical center of the workpiece
$${{OZ}_{s}}^{uuu} .$$
before measurement, by passing across a cylindrical through hole axis (103), a quarter volume of the inner circular hole test workpiece (1) is cut off from the workpiece, along two planes of symmetry perpendicular to each other, X_{c}—O—Z_{c} and Y_{c}—O—Z_{c}, as a sample (101); wherein the sample (101) includes a measurement and placement plane (105), as well as an inner hole surface (102) to be measured.

3. The method for determining initiation position of fretting fatigue cracks according to claim 1, wherein the Step 2 comprises: 201: With the measurement and placement plane (105) acting as the placement plane, the sample 101 is placed on a stage of an optical microscope such as a white light interferometer or a laser confocal microscope;
By adjusting the sample (101) based on the sample coordinate system O—XₛYₛZₛ (5), the inner hole axis (103) of the inner hole surface (102) to be measured to be parallel to the X_{w} axis of the microscope coordinate system (3), and the microscope scanning beam (302) irradiates the bottom position at center of the inner hole surface (102) to be measured, so as to ensure that the inner hole surface (102) to be measured is perpendicular to the direction in which the microscope scanning beam (302) is located;
Measurement is performed along the real contact orientation between the inner hole surface (102) of the inner circular hole test workpiece (1) and the pin shaft (2), so that a scanning path (303) of the microscope is perpendicular to the inner hole axis (103), in order to measure the surface morphology and profile image of the inner hole surface (102) of the sample (101).

4. The method for determining initiation position of fretting fatigue cracks according to claim 1, wherein the first target area (102a) and the second target area (102b) are rectangular, and the morphological coverage of the first target area (102a) and the second target area (102b) ranges from 75% to 90%.
